(19) United States
(12) Patent Application Publication
(10) Pub. No.: US 2026/0196975 A1
(43) Pub. Date: Jul. 9, 2026

(54) AUDIO AMPLIFIER WITH CLIPPING CONTROL

(71) Applicant: MONOLITHIC POWER SYSTEMS, INC., KIRKLAND, WA (US)

(72) Inventors: Liang-Hao CHEN, Hsinchu County (TW); Po-Hsien HUANG, Hsinchu County (TW); Hongguang DONG, Chandler, AZ (US); Yu-Huei LEE, New Taipei City (TW)

(21) Appl. No.: 19/015,525

(22) Filed: Jan. 9, 2025

(51) Int. Cl. H03F 3/217; H03F 1/02; H03F 3/187

(52) U.S. Cl. CPC H03F 3/2171; H03F 1/0222; H03F 3/187; H03F 2200/03; H03F 2200/258; H03F 2200/351; H03F 2200/66

(57) ABSTRACT

A control circuit for an audio amplifier includes a reference voltage generator and a voltage limiter. The reference voltage generator generates a first reference voltage and a second reference voltage according to a power supply voltage of the audio amplifier. The voltage limiter receives an audio input signal, the first reference voltage and the second reference voltage, and generates an adjusted audio signal according to the audio input signal, the first reference voltage, and the second reference voltage. The adjusted audio signal is limited to the first reference voltage when a voltage level of the audio input signal is higher than the first reference voltage, and the audio input signal is limited to the second reference voltage when the voltage level of the audio input signal is lower than the second reference voltage.

### TECHNICAL FIELD

The present disclosure relates to an audio amplifier, and more particularly, to an audio amplifier with clipping control.

### DISCUSSION OF THE BACKGROUND

An audio amplifier is an electronic device designed to magnify the amplitude of audio signals, making them powerful enough to drive speakers and produce sound. The audio amplifiers are used in various applications, such as home audio systems, headphones, and car audio setups. However, the performance of an audio amplifier is fundamentally limited by its power supply.

FIG. 1 illustrates the working principle of an audio amplifier waveforms with an input signal S1 and an output signal S2. For instance, the input signal S1 is depicted as an ideal sine wave for illustration purpose. The audio amplifier magnify the input signal S1 and provides the output signal S2 that is proportional to the audio input signal. However, when the output signal S2 of the audio amplifier exceeds the capability of the audio amplifier, clipping occurs. Specifically, as the voltage of the output signal S2 exceeds the power supply voltage PVDD of the audio amplifier, the signal is cut and limited to the maximum value (i.e., PVDD). Consequently, the output signal S2′ is clipped and appears as a distorted square wave. As a result, compared to the ideal output signal S2 having the waveform that mimics the sine wave of the input signal S1 shown in FIG. 1, the distortion of the output signal S2′ produces noticeable and disturbing audible noise. Moreover, since the audio amplifier produces more power when clipping occurs, this may damage the speaker, and may further damage the amplifier's power stage.

### SUMMARY

One aspect of the present disclosure provides a control circuit for an audio amplifier. The control circuit includes a reference voltage generator and a voltage limiter. The reference voltage generator generates a first reference voltage and a second reference voltage according to a power supply voltage of the audio amplifier. The voltage limiter receives an audio input signal, the first reference voltage and the second reference voltage, and generates an adjusted audio signal according to the audio input signal, the first reference voltage, and the second reference voltage. The adjusted audio signal is limited to the first reference voltage when a voltage level of the audio input signal is higher than the first reference voltage, and the adjusted audio signal is limited to the second reference voltage when the voltage level of the audio input signal is lower than the second reference voltage

Another aspect of the present disclosure provides an audio amplifier integrated circuit (IC). The audio amplifier IC includes an input voltage clipper and an audio amplifier. The input voltage clipper generates a first amplitude according to a power supply voltage, and generates an adjusted audio signal according to an audio input signal and the first amplitude, wherein an amplitude of the adjusted audio signal is not greater than the first amplitude. The audio amplifier is coupled to the input voltage clipper and amplifies the adjusted audio signal and provide an output signal. A voltage level of the output signal is limited to no greater than the power supply voltage of the audio amplifier.

Another aspect of the present disclosure provides a Class-D audio amplifier. The Class-D audio amplifier includes an input voltage clipper and an audio amplifier. The input voltage clipper generates a first amplitude according to a power supply voltage, and generates an adjusted audio signal according to an audio input signal and the first amplitude. An amplitude of the adjusted audio signal is not greater than the first amplitude. The audio amplifier is coupled to the input voltage clipper and amplifies the adjusted audio signal to provide an audio output signal. An amplitude of the audio output signal is limited to a value of the power supply voltage of the audio amplifier.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 illustrates the waveforms of an input signal and an output signal of an audio amplifier.

FIG. 2 illustrates a Class-D audio amplifier according to one embodiment of the present disclosure.

FIG. 3 illustrates a circuit diagram of a Class-D audio amplifier according to another embodiment of the present disclosure.

FIG. 4 illustrates the working principle of the input voltage clipper in FIG. 3.

FIG. 5 illustrates a control circuit according to one embodiment of the present disclosure.

FIG. 6 illustrates a control circuit according to another embodiment of the present disclosure.

FIG. 7 illustrates a Class-D audio amplifier according to another embodiment of the present disclosure.

### DETAILED DESCRIPTION

The following description accompanies drawings, which are incorporated in and constitute a part of this specification, and which illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

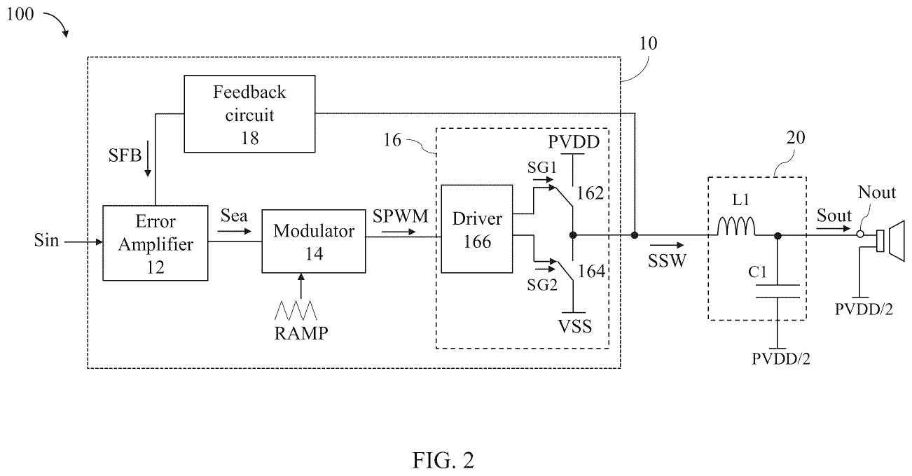

FIG. 2 illustrates a Class-D audio amplifier 100 according to one embodiment of the present disclosure. The Class-D audio amplifier 100 includes an error amplifier 12, a modulator circuit 14, a power stage circuit 16, a feedback circuit 18, and a filter 20. In one embodiment, the error amplifier 12, the modulator circuit 14, the power stage circuit 16, and the feedback circuit 18 are integrated as an audio amplifier IC 10. The error amplifier 12 receives the audio input signal Sin with the feedback signal SFB indicating the audio output signal Sout, and generates the error signal Sea. The modulator circuit 14 receives the error signal Sea and a ramp signal RAMP and generate a pulse width modulation (PWM) control signal SPWM. The power stage circuit 16 receives the PWM control signal SPWM, and generate the output signal SSW according to the PWM control signal SPWM. In one embodiment, the power stage circuit 16 includes switches 162 and 164, and a driver circuit 166. In this embodiment, the switches 162 and 164 are coupled in series between the power supply input node to receive the power supply voltage PVDD and the reference node to receive the reference voltage level VSS. In response to the PWM control signal SPWM, the driver circuit 166 provides a driving signal SG1 to the control terminal of the switch 162, and provides a driving signal SG2 to the control terminal of the switch 164 according to the PWM control signal SPWM. Accordingly, the switch 162/164 performs a switching operation by turning on and turning off alternately in response to the driving signal SG1/SG2. For example, when the driving signal SG1/SG2 is at a high voltage level (V_{GS}≥Vth), the switch 162/164 is turned on, and when the driving signal SG1/SG2 is at a low voltage level (V_{GS}<Vth), the switch 162/164 is turned off. The low pass filter 20 is coupled to the output terminal Nout to filter the output signal SSW and generate the audio output signal Sout.

The feedback circuit 18 generates a feedback signal SFB indicating the output signal Sout. In one embodiment, the feedback circuit 18 receives the output signal SSW and generates the feedback signal SFB. In another embodiment, the feedback circuit 18 receives the audio output signal Sout and generates the feedback signal SFB.

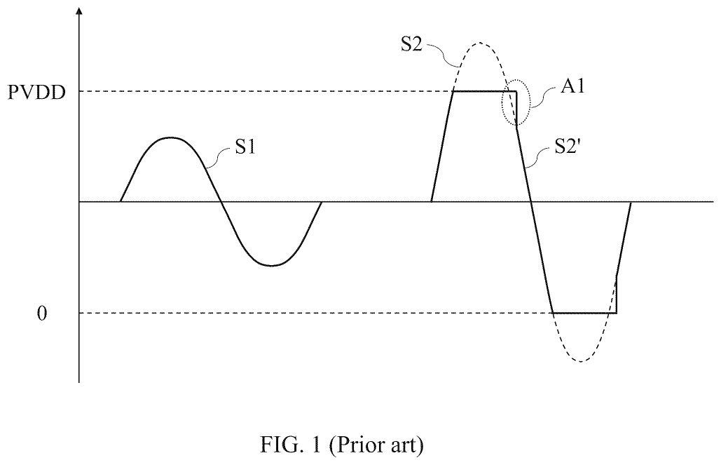

As stated before, clipping occurs when the audio output signal Sout exceeds the capability of the Class-D audio amplifier 100, for example, the maximum duty cycle of the PWM control signal SPWM is limited to 100%, and the minimum duty cycle of the PWM control signal SPWM is limited to 0. In this case, the feedback signal SFB for indicating the clipped audio output signal (e.g., S2′ as shown in FIG. 1) may not accurately represent the target audio output signal (e.g., S2 as shown in FIG. 1). In other words, the error signal Sea is not accurate (e.g., due to the difference between the S2 and S2′ during clipping), thereby leading to overcompensation of the control loop. This causes the control loop to be inaccurate and unstable. One way to solve this issue is to detect whether the duty cycle of the PWM control signal SPWM is 100% or 0%, and adjust the feedback loop accordingly. Another way is to detect whether the output level reaches the maximum or minimum of the power supply. However, both method requires involving the feedback control loop, and therefore there is delay to respond. Instead, in present disclosure, an input voltage clipper is used to create a cut input signal that is proportional to the desired output signal when the clipping occurs. As a result, this prevents the control loop from being affected by the inaccurate feedback information, and achieves faster transient response and less distortion.

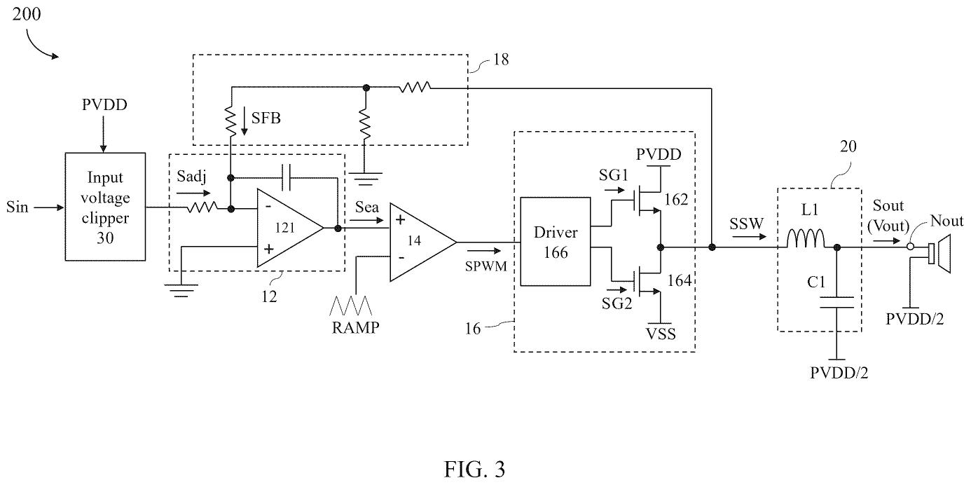

FIG. 3 illustrates a circuit diagram of a Class-D audio amplifier 200 according to one embodiment of the present disclosure. The Class-D audio amplifier 200 includes an input voltage clipper 30. In one embodiments, the input voltage clipper 30 receives the audio input signal Sin, generates a first amplitude according to the power supply voltage PVDD, and generates the adjusted audio signal Sadj having an amplitude no greater than the first amplitude. Therefore, the audio output signal Sout of the Class-D audio amplifier 200 is limited within a second amplitude. Specifically, the voltage level of the output signal Sout is limited to not greater than the power supply voltage PVDD, and not less than the reference voltage level VSS.

In one embodiment, the error integrator receives the adjusted audio signal Sadj and the feedback signal SFB, and generates the error signal Sea according to the adjusted audio signal Sadj and the feedback signal SFB. For instance, the error integrator includes the operational amplifier 121 and a resistor coupled to the inverting input terminal of the operational amplifier 121, and a capacitor coupled between the inverting input terminal and the output terminal of the operational amplifier 121.

In one embodiment, the modulator circuit 14 includes a comparator configured to compare the error signal Sea with the ramp signal RAMP (such as a triangular wave signal) so as to generate the PWM control signal SPWM.

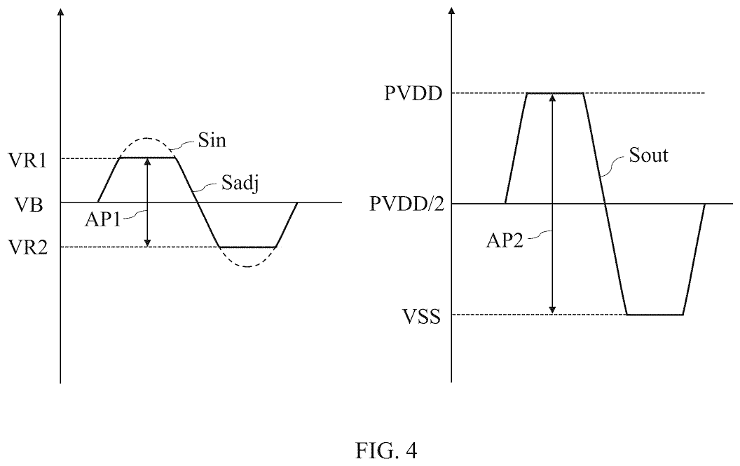

FIG. 4 illustrates the working principle of the input voltage clipper 30 according to one embodiment of the present disclosure. As shown in FIG. 4, given the audio input signal Sin as an ideal sine wave, the input voltage clipper 30 generates the adjusted audio signal Sadj according to the audio input signal Sin. Specifically, when the audio input signal Sin is greater than the first reference voltage VR1, the adjusted audio signal Sadj is limited to the first reference voltage VR1. Similarly, when the audio input signal Sin is less than the second reference voltage VR2, the adjusted audio signal Sadj is limited to the second reference voltage VR2. In addition, when the audio input signal Sin is between the first reference voltage VR1 and the second reference voltage VR2, the adjusted audio signal Sadj is the same as the audio input signal Sin.

In such case, the audio output signal Sout resembles the waveform of the adjusted audio signal Sadj. Specifically, as shown in FIG. 4, the adjusted audio signal Sadj is controlled within an amplitude AP1 between the first reference voltage VR1 and the second reference voltage VR2, and the voltage level of the audio output signal Sout is controlled within an amplitude AP2 between the power supply voltage PVDD and the reference voltage level VSS.

Since the adjusted audio signal Sadj is clipped by the input voltage clipper 30, the feedback information generated represents the accurate audio output signal Sout. Furthermore, as the audio output signal Sout does not exceed the capability of the Class-D audio amplifier 200, there is no distortion (e.g., region A1 as shown in FIG. 1). In other words, the input voltage clipper 30 prevents the control loop of the Class-D audio amplifier 200 from being affected by the feedback interference caused by hard clipping, and thus achieves faster transient response and less distortion.

In the present embodiment, for a single-ended Class-D amplifier as shown in FIG. 3, the switches 162 and 164 of the power stage 16 are coupled between the power supply voltage PVDD and the reference voltage level VSS (e.g., 0V), and the audio output signal Sout is biased at

$$\frac{PVDD}{2} .$$

In such case, the capacitor C1 and the speaker are coupled in parallel between the output voltage Vout and

$$\frac{PVDD}{2} .$$

However, the present disclosure is not limited thereto. In one embodiment, the switches 162 and 164 of the power stage may be are coupled between the power supply voltage +PVDD and the negative reference voltage-PVDD, and the audio output signal Sout should be biased at 0V. In such case, the capacitor C1 and the speaker is coupled in parallel between the output voltage Vout and the 0V.

In one embodiment, the input voltage clipper 30 includes a reference voltage generator and a voltage limiter. The reference voltage generator is configured to generate the first reference voltage VR1 and the second reference voltage VR2 according to the power supply voltage PVDD of the audio amplifier 200. The voltage limiter is configured to generate the adjusted audio signal Sadj according to the audio input signal Sin, the first reference voltage VR1, and the second reference voltage VR2.

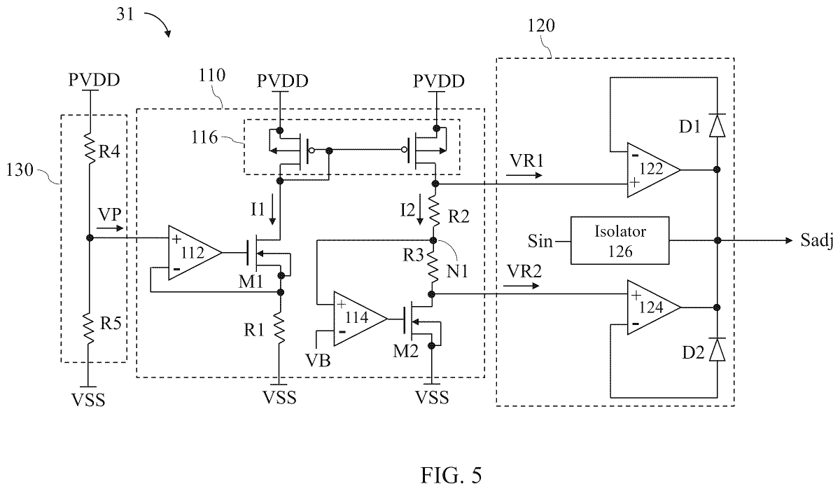

For example, FIG. 5 illustrates a control circuit 31 according to one embodiment of the present disclosure. In one embodiment, the control circuit 31 can be adopted as the input voltage clipper 30. The control circuit 31 includes a reference voltage generator 110 and a voltage limiter 120. The reference voltage generator 110 generates a first reference voltage VR1 and a second reference voltage VR2 according to a power supply voltage (e.g., PVDD). In one embodiment, the power supply voltage PVDD is the maximum voltage that the Class-D audio amplifier 200 delivers.

In the present embodiment, the first reference voltage VR1 represents an upper bound that corresponds to the power supply voltage PVDD, which is the maximum voltage of the output signal SSW when the duty cycle is 100%. Also, the second reference voltage VR2 represents a lower bound that corresponds to the reference voltage level VSS, which is the minimum voltage of the output signal SSW when the duty cycle is 0%.

Once the first reference voltage VR1 and the second reference voltage VR2 are generated, the voltage limiter 120 receives the audio input signal Sin, the first reference voltage VR1, and the second reference voltage VR2, and generates the adjusted audio signal Sadj according to the audio input signal Sin, the first reference voltage VR1, and the second reference voltage VR2.

In one embodiment, the control circuit 31 further includes a voltage divider 130. The voltage divider 130 receives the power supply voltage PVDD and generates a proportional voltage VP according to the power supply voltage PVDD. The proportional voltage VP is then provided to the reference voltage generator 110, and the reference voltage generator 110 generates the first reference voltage VR1 and the second reference voltage VR2 according to the proportional voltage VP. In one embodiment, the ratio of the voltage divider 130 is the gain of the audio amplifier 10, where the gain of the audio amplifier 10 is determined by the output voltage and the input voltage of the audio amplifier 10. For example, if the gain provided by the audio amplifier 10 is N=Vout/Vin, then the proportional voltage VP may equal to

$$( \frac{1}{N} ) * PVDD .$$

In the present embodiment, the voltage divider 130 includes resistors R4 and R5 coupled in series between the power supply voltage PVDD and the reference voltage level VSS, and the desired ratio can be achieved by setting the resistance of the resistor R4 to be (N−1) times the resistance of the resistor R5.

The reference voltage generator 110 includes a first amplifier and a second amplifier. The first amplifier receives the proportional voltage VP, and provides a current signal (e.g., the current I2) according to the proportional voltage VP. The second amplifier receives a bias voltage VB and the current signal, and provides the first reference voltage VR1 and the second reference voltage VR2 according to the bias voltage VB and the current signal.

In one embodiment, the first amplifier includes an operational amplifier 112, a transistor M1, a resistor R1, and a current mirror 116. For instance, the operational amplifier 112 has a non-inverting input terminal coupled to receive the proportional voltage VP representing the power supply voltage PVDD, an inverting input terminal, and an output terminal coupled to the control terminal of the transistor M1. The transistor M1 is coupled in series with the resistor R1. Since the inverting input terminal of the operational amplifier 112 is coupled to the resistor R1 and the second terminal of the transistor M1, the current I1 flowing through the transistor M1 is generated according to the power supply voltage PVDD and the resistance of the resistor R1. The current mirror 116 is coupled to the first terminal of the transistor M1 and configured to duplicate the current I1 that flows through the transistor M1 and the resistor R1 to generate a current I2. The current I2 is provided to the second amplifier.

The second amplifier includes an operational amplifier 114, a transistor M2, and resistors R2 and R3. For example, the transistor M2 is coupled to in series with the current mirror 116 to receive the current I2. Drop elements (e.g., resistors R2 and R3) are coupled in series on the path of the current I2 to provide the drop voltage. The operational amplifier 114 has a non-inverting input terminal coupled to the node N1 connected between the resistor R2 and the resistor R3, an inverting input terminal coupled to receive the bias voltage VB, and an output terminal coupled to the control terminal of the transistor M2. In such case, the current I2 flowing through the transistor M2 is controlled by the operational amplifier 114, and therefore the voltage of the node N1 remains at the bias voltage VB. A first terminal of the resistor R2 is configured to provide the first reference voltage VR1=VB+Vr2. Similarly, a second terminal of the resistor R3 is configured to provide the second reference voltage VR2=VB−Vr2, where Vr2 is the drop voltage provided by the resistor R2 or R3, assuming that the resistor R2 and R3 have equal resistance.

In the present embodiment, since the inverting terminal of the operational amplifier 112 is coupled to the first terminal of the resistor R1, the current I1 flowing through the resistor R1 could be expressed as:

$$\frac{VP}{R 1} = \frac{PVDD}{N * R 1} .$$

Therefore, the current I2 generated by the current mirror 116 could be expressed as

$$\frac{PVDD}{N * R 1} .$$

Therefore, in one implementation, suppose the resistance of the resistor R2 is equal to the resistance of the resistor R3, and equal to a half of the resistance of the resistor R1, the voltage across the resistor R2 could be expressed as:

$$I 2 * R 2 = ( \frac{PVDD}{N * R 1} ) * R 2 = ( \frac{PVDD}{2 N} ) .$$

Similarly, the voltage across the resistor R3 could be expressed as:

$$I 2 * R 3 = ( \frac{PVDD}{N * R 1} ) * R 3 = ( \frac{PVDD}{2 N} ) .$$

Furthermore, the operational amplifier 114 may control the voltage at the second terminal of the resistor R2 (i.e., the first terminal of the resistor R3) to be at the bias voltage VB received from its inverting input terminal. As a result, the first reference voltage VR1 can be provided through the first terminal of the resistor R2, where the first reference voltage VR1 is equal to

$$VB + ( \frac{PVDD}{2 N} ) .$$

Also, the second reference voltage VR2 can be provided through the second terminal of the resistor R3, where the second reference voltage VR2 is equal to

$$VB - ( \frac{PVDD}{2 N} ) .$$

In such case, the first reference voltage VR1 correspond to the output signal Sout having the power supply voltage PVDD. The second reference voltage VR2 correspond to the output signal Sout having the reference voltage level VSS. In one embodiment, to further prevent the hard clipping, the first reference voltage VR1 may be set to correspond to a voltage lower than PVDD and the second reference voltage VR2 may be set to correspond to a voltage higher than VSS. Furthermore, in the present embodiment, the bias voltage VB is the common mode voltage of the audio input signal Sin. For example, suppose the audio input signal Sin has a maximum voltage at 3.3V and a minimum voltage at 0V, the bias voltage VB may be the center voltage between 3.3V and 0V (i.e. 1.65V), however, the present disclosure is not limited thereto. In one embodiment, instead of setting the bias voltage VB to the center voltage, the bias voltage VB may be set to other suitable voltages according to the operation voltage range of the audio amplifier 10.

The voltage limiter 120 limits the adjusted audio signal Sadj within the voltage range between the first reference voltage VR1 and the second reference voltage VR2. In one embodiment, the voltage limiter 120 includes operational amplifiers 122 and 124 and diodes D1 and D2. The operational amplifier 122 has a first input terminal (e.g., non-inverting input terminal) for receiving the first reference voltage VR1, a second input terminal (e.g., inverting input terminal), and an output terminal. The diode D1 has an anode coupled to the output terminal of the operational amplifier 122, and a cathode coupled to the second input terminal of the operational amplifier 122. In such case, when the voltage level of the audio input signal Sin is lower than the first reference voltage VR1, the diode D1 is cut off, and the adjusted audio signal Sadj is not affected by the operational amplifier 122. However, when the voltage level of the audio input signal Sin is higher than the first reference voltage VR1, the diode D1 is conducted, and the output of the operational amplifier 122 is pulled down and limited to the first reference voltage VR1.

The operational amplifier 124 has a first input terminal (e.g., non-inverting input terminal) for receiving the second reference voltage VR2, a second input terminal (e.g., inverting input terminal), and an output terminal. The diode D2 has an anode coupled to the second input terminal of the operational amplifier 124, and a cathode coupled to the output terminal of the operational amplifier 124. In such case, when the voltage level of the audio input signal Sin is higher than the second reference voltage VR2, the diode D2 is cut off, and the adjusted audio signal Sadj is not affected by the operational amplifier 124. However, when the voltage level of the audio input signal Sin is lower than the second reference voltage VR2, the diode D2 is conducted, and the output of the operational amplifier 124 is pulled high and limited to the second reference voltage VR2.

It should be noted that the structure of the control circuit 31 shown in FIG. 5 is provided as an example for illustration purpose, but is not to limit the present disclosure. In some other embodiments, the control circuit 31 may adopt other structures and/or other components to generate the reference voltages for limiting the audio input signal Sin and produce the adjusted audio signal Sadj. For example, in the present embodiment, to protect the input source that provides the audio input signal Sin, the voltage limiter 120 may further include an isolator 126. The isolator 126 passes the audio input signal Sin to the output terminals of the operational amplifiers 122 and 124, and protect the audio input signal Sin form being affected as the operational amplifiers 122 and 124 produce the adjusted audio signal Sadj. However, the present disclosure is not limited thereto. In one embodiment, the isolator 126 may be omitted. It should be noted that diodes D1 and D2 may be rectifiers and may be replaced by MOSFETs in some embodiments.

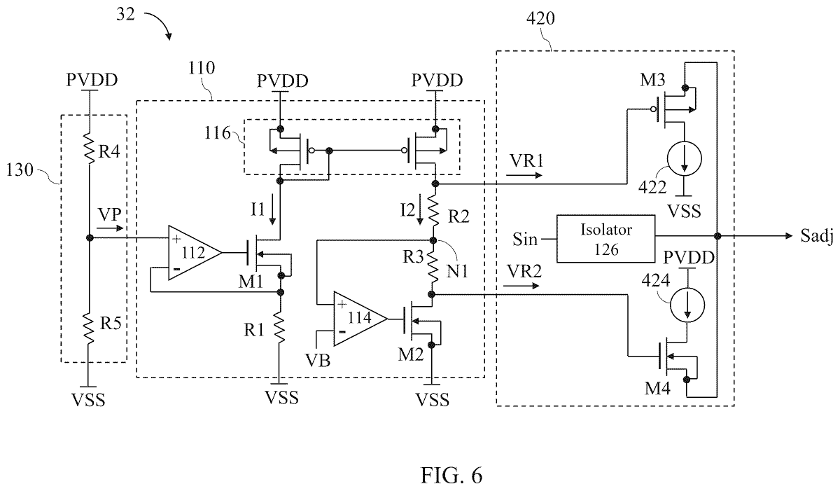

FIG. 6 illustrates a control circuit 32 according to another embodiment of the present disclosure. The control circuit 32 is different from the control circuit 31 in that the voltage limiter 420 of the control circuit 32 includes transistors M3, and M4. In the present embodiment, the transistor M3 is a P-type transistor comprising a first terminal (e.g., the drain) coupled to the reference voltage level VSS via a current source 422, a second terminal (e.g., the source) coupled to receive the input signal Sin and generate the adjusted audio signal Sadj, and a gate terminal coupled to receive the first reference voltage VR1. In such case, when the input signal Sin is lower than the first reference voltage VR1 (i.e., VGS<Vth), the transistor M3 is turned off, and the adjusted audio signal Sadj is not affected by the transistor M3 and the current source 422. However, when the input signal Sin is higher than the first reference voltage VR1 (i.e., VGS>Vth), the transistor M3 is turned on to pull down the voltage level of the audio input signal Sin, thereby limiting the adjusted audio signal Sadj to the first reference voltage VR1.

Similarly, the transistor M4 is an N-type transistor comprising a first terminal (e.g., the drain) is coupled to the power supply voltage PVDD via a current source 424, a second terminal (e.g., the source) coupled to receive the input signal Sin and generate the adjusted audio signal Sadj, and a gate terminal coupled to receive the second reference voltage VR2. In such case, when the input signal Sin is higher than the second reference voltage VR2 (i.e., VGS<Vth), the transistor M4 is turned off, and the adjusted audio signal Sadj is not affected by the transistor M4 and the current source 424. However, when the input signal Sin is lower than the second reference voltage VR2 (i.e., VGS>Vth), the transistor M4 is turned on to pull high the voltage level of the audio input signal Sin, thereby by limiting the adjusted audio signal Sadj to the second reference voltage VR2.

It should be noted that the above discussion is meant to be illustrative of the principles and various embodiments of the present disclosure. Numerous variations and modifications will become apparent to those skilled in the art once the present disclosure is fully appreciated.

In one embodiment, the input voltage clipper 30 is implemented with the control circuit 31 and 32 that generates the reference voltages VR1 and VR2 according to the power supply voltage PVDD and limit the input of the audio amplifier 200 within an amplitude AP1 between the first reference voltage VR1 and the second reference voltage VR2, so the voltage level of the output signal Sout of the audio amplifier 200 can be controlled within an amplitude AP2 between the power supply voltage PVDD and the reference voltage level VS, thereby avoiding or reducing the occurrence of audio clipping at the output side of the audio amplifier 200. As a result, the incorrect feedback information caused by output signal clipping can be avoided, and the overcompensation as well as the distortion caused by the incorrect feedback information can be avoided or reduced. Furthermore, since the input voltage clipper 30 can perform the input signal clipping by tracking the power supply voltage PVDD and the voltage of the input signal of the audio amplifier 200 without monitoring the voltage of the output signal of the audio amplifier 200, the control scheme of the input voltage clipper 30 can have a higher response speed.

In one embodiment, the input voltage clipper 30 may be integrated with some other circuits in the Class-D audio amplifier 200. For example, in one embodiment, the Class-D audio amplifier 200 can be a digital audio amplifier that receives digital audio input signal. In such case, the Class-D audio amplifier 200 may further include a digital-to-analog circuit (DAC) for converting the digital audio input signal into the analog audio input signal Sin. In such case, the input voltage clipper 30 may be integrated within the DAC. However, the present disclosure is not limited thereto. In one embodiment, the input voltage clipper 30 may be designed independently of the DAC, and may be coupled between the DAC and the audio amplifier 10.

Furthermore, in one embodiment, the Class-D audio amplifier 200 may include a clipping detection circuit. The clipping detection circuit generates a warning signal when the voltage limiter 120 or 220 limits the adjusted audio signal Sadj to the first reference voltage VR1 for more than a period of time. For example, a counter may start counting when a current flowing through the diode D1 is detected, and the warning signal may be issued when the counter reaches a predetermined number. Also, the clipping detection circuit generates a warning signal when the voltage limiter 120 or 220 limits the adjusted audio signal Sadj to the second reference voltage VR2 for more than a period of time. The warning signals can be adopted to indicate the events of excessive input voltage and alert the control circuit that provides the input signals Sin to take corresponding actions.

In one embodiment, the input voltage clipper 30 and the audio amplifier 10 can be integrated as in an audio amplifier integrated circuit (IC) while the low pass filter 20 including the inductor L1 and the capacitor C1 can be discrete from the audio amplifier IC.

Although the control circuits 31, 32 and the input voltage clipper 30 introduced in the previous embodiments are applied for a single-ended audio amplifier. However, the present disclosure is not limited thereto. In one embodiment, the control circuits 31, 32 and the input voltage clipper 30 may be applied for differential audio amplifiers.

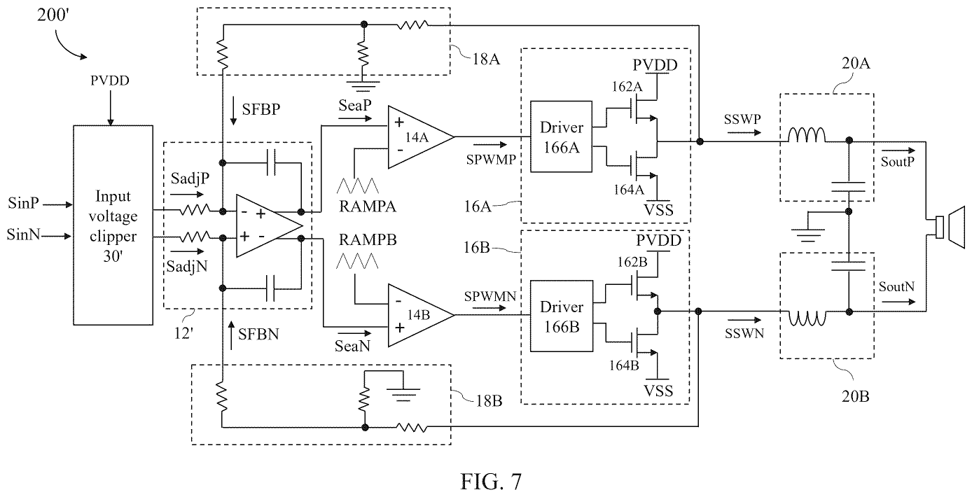

FIG. 7 illustrates a Class-D audio amplifier 200′ according to another embodiment of the present disclosure. The Class-D audio amplifier 200′ is different from the Class-D audio amplifier 200 shown in FIG. 3 in that the Class-D audio amplifier 200′ is a fully differential amplifier. In such case, the input voltage clipper 30′ may be used to limit both the positive audio input signal SinP and the negative audio input signal SinN so as to generate the positive adjusted audio signal SadjP and the negative adjusted audio signal SadjN having their amplitudes within the corresponding reference voltages (e.g., between the first reference voltage VR1 and the second reference voltage VR2).

In one embodiment, a similar structure of the input voltage clipper 30 shown in FIG. 5 can be adopted to implement the input voltage clipper 30′. For example, the input voltage clipper 30′ may include the voltage divider 130 and the reference voltage generator 110 for generating the first reference voltage VR1 and the second reference voltage VR2. In addition, the input voltage clipper 30′ may include two voltage limiters 120, one for generating the positive adjusted audio signals SadjP according to the positive input signal SinP, the first reference voltage VR1 and the second reference voltage VR2, and another for generating the negative adjusted audio signals SadjN according to the negative input signal SinN according to the negative input signal SinN, the first reference voltage VR1 and the second reference voltage VR2

In the present embodiment, the error integrator 12′ receives the adjusted audio signal SadjP and the feedback signals SFBP generated by the feedback circuits 18A so as to generate the error signals SeaP. The error integrator 12′ further generates the error signals SeaN according to the adjusted audio signal SadjN and the feedback signals SFBN generated by the feedback circuits 18B. The modulator 14A generates the positive PWM control signal SPWMP according to the positive error signal SeaP and the ramp signal RAMPA, and the positive PWM control signal SPWMP is sent to the driver circuit 166A of the power stage circuit 16A for driving the switches 162A and 164A and providing the positive output signal SSWP. Likewise, the modulator 14B generates the negative PWM control signal SPWMN according to the error signal SeaN and the ramp signal RAMPB, and the negative PWM control signal SPWMN is sent to the driver circuit 166B of the power stage circuit 16B for driving the switches 162B and 164B and providing the negative output signal SSWN. Finally, the low pass filters 20A and 20B would filter the high frequency output signals SSWP and SSWN and provide the positive audio output signal SoutP and the negative audio output signal SoutN respectively to the speaker.

It should be noted that although the signals are described as positive signals and negative signals as differential signals in the Class-D audio amplifier 200′, the terms of “positive” and “negative” are solely to denote their relative roles within the differential pairs, rather than to specify their actual voltage levels. For example, the audio input signal SinN, which is referred to as the negative audio input signal, may not necessarily have a voltage level below the ground voltage. In one embodiment, both the positive audio input signal SinP and the negative audio input signal SinN can be positive and higher than the ground voltage. Alternatively, in some other embodiments, the negative audio input signal SinN may actually be negative and lower than the ground voltage. Accordingly, depending on the voltage levels of the signals specified in the Class-D audio amplifier 200′, the input voltage clipper 30′ and the differential audio amplifier may also be adjusted correspondingly and appropriately.

In summary, the control circuits, the audio amplifier circuits, and the audio ICs provided by the embodiments of the present disclosure can adjust the input signal of an audio amplifier within a predetermined voltage range so as to avoid the output signal of the audio amplifier from being clipped. Consequently, the incorrect feedback information caused by output signal clipping can be avoided, thereby allowing the audio amplifier to have a higher response speed and produce less distortion.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A control circuit for an audio amplifier, comprising:
a reference voltage generator configured to generate a first reference voltage and a second reference voltage according to a power supply voltage of the audio amplifier;
a voltage limiter configured to receive an audio input signal, the first reference voltage and the second reference voltage, and generate an adjusted audio signal according to the audio input signal, the first reference voltage, and the second reference voltage, wherein the adjusted audio signal is limited to the first reference voltage when a voltage level of the audio input signal is higher than the first reference voltage, and the adjusted audio signal is limited to the second reference voltage when the voltage level of the audio input signal is lower than the second reference voltage.

2. The control circuit of claim 1, further comprising:
a voltage divider configured to receive the power supply voltage and generate a proportional voltage;
wherein the proportional voltage is provided to the reference voltage generator, and the first reference voltage and the second reference voltage are generated according to the proportional voltage.

3. The control circuit of claim 2, wherein a ratio of the voltage divider is a gain of the audio amplifier.

4. The control circuit of claim 2, wherein the reference voltage generator comprises:
a first amplifier configured to receive the proportional voltage, and provide a current signal according to the proportional voltage;
a second amplifier configured to receive a bias voltage and the current signal, and provide the first reference voltage and the second reference voltage according to the bias voltage and the current signal.

5. The control circuit of claim 2, wherein the reference voltage generator comprises:
a first operational amplifier having a first input terminal configured to receive the proportional voltage, a second input terminal, and an output terminal;
a first transistor having a first terminal, a second terminal coupled to the second input terminal of the first operational amplifier, and a control terminal coupled to the output terminal of the first operational amplifier;
a current mirror coupled to the first terminal of the first transistor and configured to duplicate a first current flowing through the first transistor to generate a second current;
a first drop element coupled to in series with the current mirror and configured to receive the second current, and provide the first reference voltage;
a second drop element coupled in series with the first drop element, and configured to provide the second reference voltage;
a second transistor having a first terminal, a second terminal, and a control terminal, wherein the second transistor is coupled in series with the first drop element and the second drop element; and
a second operational amplifier having a first input terminal coupled to a node connected between the first drop element and the second drop element, a second input terminal configured to receive a bias voltage, and an output terminal coupled to the control terminal of the second transistor.

6. The control circuit of claim 1, wherein the voltage limiter comprises:
a third operational amplifier having a first input terminal configured to receive the first reference voltage, a second input terminal, and an output terminal configured to limit the adjusted audio signal when the voltage level of the audio input signal is higher than the first reference voltage;
a first rectifier having a first terminal coupled to the output terminal of the third operational amplifier, and a second terminal coupled to the second input terminal of the third operational amplifier;
a fourth operational amplifier having a first input terminal configured to receive the second reference voltage, a second input terminal, and an output terminal configured to limit the adjusted audio signal when the voltage level of the audio input signal is lower than the second reference voltage; and
a second rectifier having a first terminal coupled to the second input terminal of the fourth operational amplifier, and a second terminal coupled to the output terminal of the fourth operational amplifier.

7. The control circuit of claim 1, wherein the voltage limiter comprises:
a first transistor having a first terminal, a second terminal, and a control terminal coupled to receive the first reference voltage, wherein the second terminal of the first transistor is configured to receive the audio input signal and provide the adjusted audio signal, and the first transistor is turned on to pull-down a voltage level of the audio input signal when a voltage level of the audio input signal is higher than the first reference voltage; and
a second transistor having a first terminal, a second terminal, and a control terminal coupled to receive the second reference voltage, wherein the second terminal of the second transistor is configured to receive the audio input signal and provide the adjusted audio signal, and the second transistor is turned on to pull-high the voltage of the audio input signal when the voltage level of the audio input signal is lower than the second reference voltage.

8. The control circuit of claim 1, further comprising:
a feedback circuit configured to generate a feedback signal indicating an output signal; and
an error amplifier configured to receive the adjusted audio signal and the feedback signal, and generate an error signal according to the adjusted audio signal and the feedback signal.

9. The control circuit of claim 1, further comprising:
a first switch having a first terminal, a second terminal and a control terminal, wherein the first terminal of the first switch is configured to receive the power supply voltage;
a second switch having a first terminal, a second terminal and a control terminal, wherein the first terminal of the second switch is coupled to the second terminal of the first switch and is configured to provide an output signal, and the second terminal of the second switch is coupled to a reference voltage level; and
a driver circuit configured to provide a first driving signal to the first switch according to a pulse width modulation (PWM) control signal, and to provide a second driving signal to the second switch according to the PWM control signal.

10. An audio amplifier integrated circuit (IC) comprising:
an input voltage clipper configured to receive an audio input signal, generate a first amplitude according to a power supply voltage, and generate an adjusted audio signal according to the audio input signal and the first amplitude, wherein an amplitude of the adjusted audio signal is not greater than the first amplitude; and
an audio amplifier coupled to the input voltage clipper and configured to amplify the adjusted audio signal and provide an output signal;
wherein a voltage level of the output signal is limited to no greater than the power supply voltage of the audio amplifier.

11. The audio amplifier IC of claim 10, wherein the input voltage clipper comprises:
a voltage divider configured to receive the power supply voltage and generate a proportional voltage according to the power supply voltage, wherein a ratio of the voltage divider is a gain of the audio amplifier.

12. The audio amplifier IC of claim 11, wherein the input voltage clipper further comprises:
a reference voltage generator configured to generate a first reference voltage and a second reference voltage according to the proportional voltage, and a difference between the first reference voltage and the second reference voltage is the first amplitude.

13. The audio amplifier IC of claim 12, wherein the input voltage clipper further comprises:
a voltage limiter configured to receive the audio input signal, the first reference voltage and the second reference voltage, and generate the adjusted audio signal according to the audio input signal, the first reference voltage, and the second reference voltage;
wherein the adjusted audio signal is limited to the first reference voltage when the voltage level of the audio input signal is higher than the first reference voltage, and the audio input signal is limited to the second reference voltage when the voltage level of the audio input signal is lower than the second reference voltage.

14. The audio amplifier IC of claim 10, wherein the first amplitude is proportional to the power supply voltage.

15. The audio amplifier IC of claim 12, wherein the reference voltage generator comprises:
a first operational amplifier having a first input terminal configured to receive the proportional voltage, a second input terminal, and an output terminal;
a first transistor having a first terminal, a second terminal coupled to the second input terminal of the first operational amplifier, and a control terminal coupled to the output terminal of the first operational amplifier;
a current mirror coupled to the first terminal of the first transistor and configured to duplicate a first current flowing through the first transistor to generate a second current;
a first drop element coupled to in series with the current mirror and configured to receive the second current, and provide the first reference voltage;
a second drop element coupled in series with the first drop element, and configured to provide the second reference voltage;
a second transistor having a first terminal, a second terminal, and a control terminal, wherein the second transistor is coupled in series with the first drop element and the second drop element; and
a second operational amplifier having a first input terminal coupled to a node connected between the first drop element and the second drop element, a second input terminal configured to receive a bias voltage, and an output terminal coupled to the control terminal of the second transistor.

16. The audio amplifier IC of claim 13, wherein the voltage limiter comprises:
a third operational amplifier having a first input terminal configured to receive the first reference voltage, a second input terminal, and an output terminal configured to adjust the audio input signal when the voltage level of the audio input signal is higher than the first reference voltage;
a first rectifier having a first terminal coupled to the output terminal of the third operational amplifier, and a second terminal coupled to the second input terminal of the third operational amplifier;
a fourth operational amplifier having a first input terminal configured to receive the second reference voltage, a second input terminal, and an output terminal configured to adjust the audio input signal when the voltage level of the audio input signal is lower than the second reference voltage; and
a second rectifier having a first terminal coupled to the second input terminal of the fourth operational amplifier, and a second terminal coupled to the output terminal of the fourth operational amplifier.

17. A Class-D audio amplifier, comprising:
an input voltage clipper configured to receive an audio input signal, generate a first amplitude according to a power supply voltage, and generate an adjusted audio signal according to the audio input signal and the first amplitude, wherein an amplitude of the adjusted audio signal is not greater than the first amplitude; and
an audio amplifier circuit coupled to the input voltage clipper and configured to amplify the adjusted audio signal and provide an audio output signal;
wherein an amplitude of the audio output signal is limited to a value of the power supply voltage of the Class-D audio amplifier.

18. The Class-D audio amplifier of claim 17, wherein the input voltage clipper comprises:
a reference voltage generator configured to generate a first reference voltage and a second reference voltage according to the power supply voltage and a gain of the Class-D audio amplifier, and a difference between the first reference voltage and the second reference voltage is the first amplitude.

19. The Class-D audio amplifier of claim 18, wherein the input voltage clipper further comprises:
a voltage limiter configured to receive the audio input signal, the first reference voltage and the second reference voltage, and generate the adjusted audio signal according to the audio input signal, the first reference voltage, and the second reference voltage
wherein the adjusted audio signal is limited to the first reference voltage when a voltage level of the audio input signal is higher than the first reference voltage, and the audio input signal is limited to the second reference voltage when the voltage level of the audio input signal is lower than the second reference voltage.

20. The Class-D audio amplifier of claim 18, further comprising:
a clipping detection circuit configured to generate a warning signal when the adjusted audio signal reaches the first reference voltage for a period of time.

21. The Class-D audio amplifier of claim 18, further comprising:
a clipping detection circuit configured to generate a warning signal when the adjusted audio signal reaches the second reference voltage for a period of time.
